(19) United States
(12) Patent Application Publication
(10) Pub. No.: US 2023/0316551 A1
(43) Pub. Date: Oct. 5, 2023

(54) MOUNTING MACHINE AND METHOD FOR MEASURING SUBSTRATE HEIGHT

(71) Applicant: Panasonic Intellectual Property Management Co., Ltd., Osaka (JP)

(72) Inventors: Naoki KAMADA, Osaka (JP); Ryuji FUCHIKAMI, Fukuoka (JP)

(21) Appl. No.: 18/127,877

(22) Filed: Mar. 29, 2023

(30) Foreign Application Priority Data
Mar. 30, 2022 (JP) 2022-056479

(51) Int. Cl. G06T 7/521; G06T 7/593; H04N 13/254; H04N 13/239

(52) U.S. Cl. CPC G06T 7/521; G06T 7/593; H04N 13/254; H04N 13/239

(57) ABSTRACT

A mounting machine includes a first imaging unit that captures, as a first captured image, a first imaging region in a predetermined imaging region on a substrate illuminated with laser light, the first imaging region being smaller than the predetermined imaging region, a second imaging unit that captures, as a second captured image, a second imaging region in the predetermined imaging region, the second imaging region smaller than the predetermined imaging region and including at least a region different from the first imaging region, and a calculation unit that detects an illumination position of the laser light from at least one captured image of the first captured image or the second captured image, and calculates a height of the substrate based on the detected illumination position.

### BACKGROUND

### 1. Technical Field

The present disclosure relates to a mounting machine and a method for measuring a substrate height.

### 2. Description of the Related Art

International Publication WO2015-052755 discloses a mounting device that acquires related information regarding a substrate height of a counter region of a substrate.

A mounting device includes a mounting head that holds a component, and conveys the component to mount the component on a substrate, imaging means that includes a first imaging unit that captures the component held by the mounting head, a second imaging unit that captures a counter region of a substrate surface facing the held component, and a height-related information acquisition unit that acquires related information regarding a substrate height of the counter region of the substrate, and imaging movement means capable of moving the imaging means to a position between the component held by the mounting head and the counter region while maintaining a relative position between the first imaging unit, the second imaging unit, and the height-related information acquisition unit, the position being an imaging position at which the imaging by the first imaging unit and the second imaging unit and the acquisition of the height-related information.

### SUMMARY

The present disclosure has been made in view of the above-described circumstances of the related art, and an object of the present disclosure is to provide a mounting machine and a method for measuring a substrate height that more efficiently measure the substrate height.

The present disclosure provides a mounting machine including a first imaging unit that captures, as a first captured image, a first imaging region in a predetermined imaging region on a substrate illuminated with laser light, the first imaging region being smaller than the predetermined imaging region, a second imaging unit that captures, as a second captured image, a second imaging region in the predetermined imaging region, the second imaging region smaller than the predetermined imaging region and including at least a region different from the first imaging region, and a calculation unit that detects an illumination position of the laser light from at least one captured image of the first captured image or the second captured image, and calculates a height of the substrate based on the detected illumination position.

In addition, the present disclosure provides a method for measuring a substrate height executed by a computer connected to two cameras that capture a predetermined imaging region on a substrate illuminated with laser light. The substrate height measurement method includes capturing, as a first captured image, a first imaging region in the predetermined imaging region, the first imaging region being smaller than the predetermined imaging region, capturing, as a second captured image, a second imaging region in the predetermined imaging region, the second imaging region smaller than the predetermined imaging region and including at least a region different from the first imaging region, detecting an illumination position of the laser light from at least one captured image of the first captured image or the second captured image, and calculating a height of the substrate based on the detected illumination position.

According to the present disclosure, it is possible to more efficiently measure the substrate height.

### BRIEF DESCRIPTION OF THE DRAWINGS

FIG. 1 is a block diagram illustrating an internal configuration example of a mounting system according to a first exemplary embodiment;

FIG. 2 is a side view illustrating a use case example of the mounting system according to the first exemplary embodiment;

FIG. 3 is a side view illustrating a use case example of the mounting system according to the first exemplary embodiment;

FIG. 4 is a diagram for describing an imaging region example of each of a first camera and a second camera;

FIG. 5 is a flowchart for describing an operation procedure example of the mounting system according to the first exemplary embodiment;

FIG. 6 is a side view for describing a substrate height measurement example;

FIG. 7 is a top view for describing a substrate height measurement example;

FIG. 8 is a diagram for describing a second laser illumination example;

FIG. 9 is a diagram for describing a third laser illumination example;

FIG. 10 is a diagram for describing a fourth laser illumination example;

FIG. 11 is a diagram for describing a fifth laser illumination example; and

FIG. 12 is a diagram for describing another use case example of height measurement processing in the first exemplary embodiment.

### DETAILED DESCRIPTION

(Background of Present Disclosure)

International Publication WO2015-052755 discloses a mounting device (hereinafter, referred to as “mounting machine”) that illuminates a substrate with a spot light source and measures a substrate height based on a position of spot light appearing in image data obtained by capturing a counter region including spot light illuminated onto the substrate. The mounting machine detects the position of the spot light by extracting a pixel having a highest brightness from the image data, and measures the substrate height by comparing the detected position of the spot light with a correspondence relationship between a position of the spot light and a substrate height measured in advance by an experiment or the like.

However, in the mounting device, since it is necessary to create data indicating the correspondence relationship between the position of the spot light and the substrate height in advance to correspond to sizes of substrates and components produced by the mounting device, it is very troublesome.

In addition, since the mounting machine detects the position of the spot light by performing image processing on the entire counter region, an image processing time increases to correspond to the number of components mounted on the substrate, and thus, it is difficult to improve production efficiency of the substrate.

Hereinafter, each exemplary embodiment specifically disclosing a configuration and an action of the mounting machine and a method for measuring a substrate height according to the present disclosure will be described in detail with reference to the drawings as appropriate. It is noted that a more detailed description than need may be omitted. For example, detailed description of well-known matters and repeated description of substantially the same configuration may be omitted. This is to avoid the unnecessary redundancy in the following descriptions and to make the descriptions easier to understand for those skilled in the art. Note that the accompanying drawings and the following description are provided for those skilled in the art to fully understand the present disclosure, and are not intended to limit the subject matter described in the scope of claims.

In addition, hereinafter, in each drawing, an X direction and a Y direction are directions orthogonal to each other in a horizontal plane. A Z direction is a height direction (vertical direction) orthogonal to the X direction and the Y direction.

### First Exemplary Embodiment

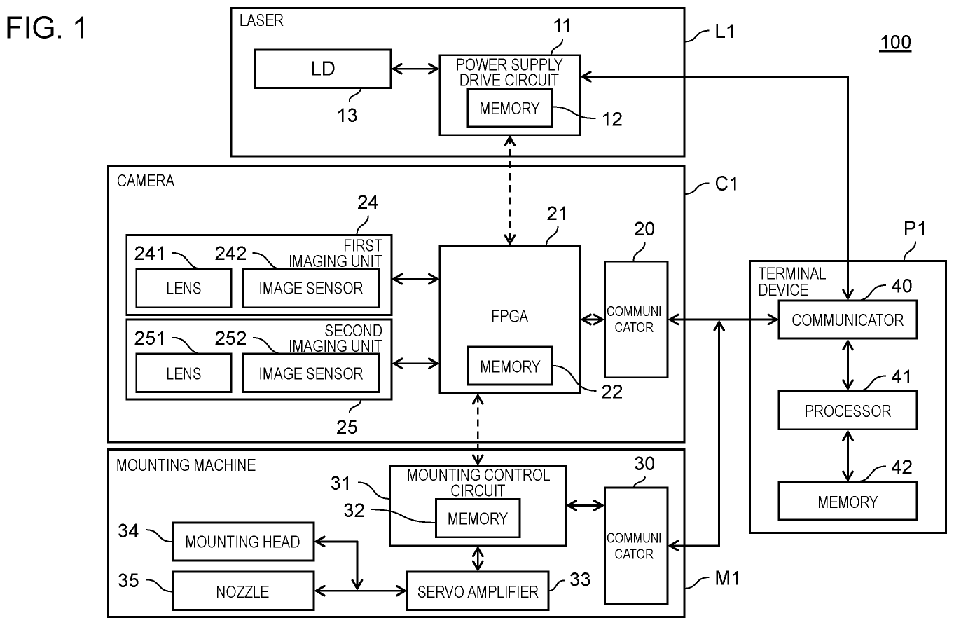

First, an internal configuration of mounting system 100 according to a first exemplary embodiment will be described with reference to FIG. 1. FIG. 1 is a diagram for describing an internal configuration example of mounting system 100 according to the first exemplary embodiment.

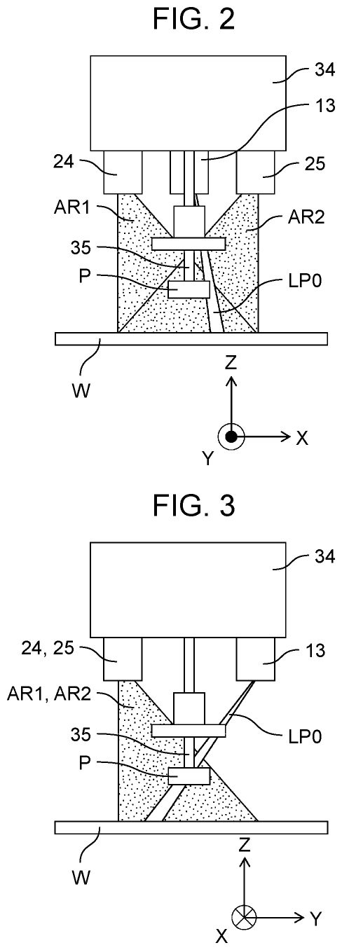

Mounting system 100 as an example of a mounting machine includes laser L1, camera C1, mounting machine M1, and terminal device P1, and produces a mounting substrate on which component P (see FIG. 2) is mounted (mounted) on substrate W (see FIG. 2). Note that mounting system 100 illustrated in FIG. 1 is an example, and is not limited thereto. For example, laser L1, camera C1, and mounting machine M1 may be integrally formed as one mounting machine. In addition, laser L1, camera C1, mounting machine M1, and terminal device P1 may be integrally formed as one mounting machine.

Laser L1 includes power supply drive circuit 11, memory 12, and laser diode (LD) 13.

Power supply drive circuit 11 is connected to terminal device P1 or camera C1 to be able to transmit and receive data. Power supply drive circuit 11 performs ON/OFF control of LD 13, control of a position of a laser illumination point, and the like based on a control command (electric signal) transmitted from processor 41 of terminal device P1 or FPGA 21 of camera C1.

Memory 12 includes, for example, a random access memory (RAM) as a work memory used when each processing of power supply drive circuit 11 is executed, and a read only memory (ROM) that stores a program and data that defines an operation of power supply drive circuit 11. Data or information generated or acquired by power supply drive circuit 11 is temporarily stored in the RAM. A program that defines the operation of power supply drive circuit 11 is written to the ROM. Memory 12 may store the position of the laser illumination point and the like.

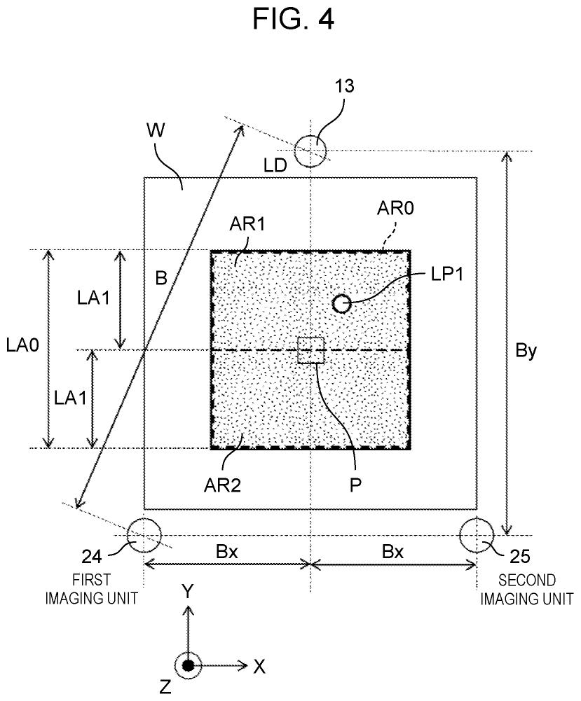

LD 13 is driven by power supply drive circuit 11 to illuminate a predetermined or random position on substrate W and in imaging region AR0 (see FIG. 4) of camera C1 with laser light. Note that the number of illumination points with which substrate W is illuminated by LD 13 may be plural.

Camera C1 includes communicator 20, FPGA 21, first imaging unit 24, and second imaging unit 25.

Communicator 20 is connected to terminal device P1 to be able to transmit and receive data. Communicator 20 outputs the control command (electric signal) transmitted from terminal device P1 to FPGA 21.

FPGA 21 performs various kinds of processing and control in an integrated manner in cooperation with memory 22. Specifically, FPGA 21 refers to a program and data retained in memory 22 and executes the program to achieve a function of each unit.

Memory 22 includes, for example, a RAM as a work memory used when each processing of FPGA 21 is executed, and a ROM that stores a program and data that defines an operation of FPGA 21. Data or information generated or acquired by FPGA 21 is temporarily stored in the RAM. A program that defines the operation of FPGA 21 is written to the ROM.

Note that FPGA 21 may be formed, for example, by using a central processing unit (CPU) or a digital signal processor (DSP).

FPGA 21 acquires each of two captured images transmitted from camera C1. FPGA 21 executes image processing of the captured images captured by first imaging unit 24 and second imaging unit 25 in parallel, and detects an illumination point of laser light appearing in at least one of two captured images. FPGA 21 outputs positional information of the detected illumination point to communicator 20, and transmits the positional information to terminal device P1.

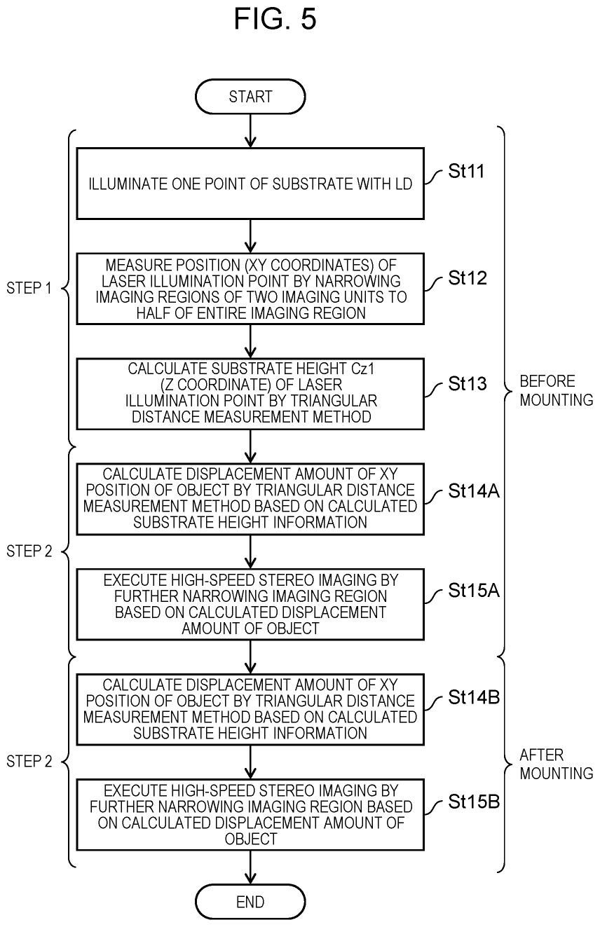

In addition, FPGA 21 causes each of first imaging unit 24 and second imaging unit 25 to capture (that is, perform stereo imaging) the same imaging region in a state where the imaging region of each of first imaging unit 24 and second imaging unit 25 is narrowed (decreased) to a region smaller than imaging region AR0 than during the measurement of the substrate height based on the control command transmitted from terminal device P1. FPGA 21 acquires a three-dimensional shape of a mounting position of component P such as a land on substrate W before component mounting (that is, step St15A illustrated in FIG. 5) based on each of the two captured images output from first imaging unit 24 and second imaging unit 25. FPGA 21 transmits the acquired three-dimensional shape data to terminal device P1 to enable calculation of the displacement amount of the mounting position of component P corresponding to the substrate height.

In addition, FPGA 21 acquires the three-dimensional shape of component P or the like mounted on substrate W after the component is mounted (that is, step St15B illustrated in FIG. 5) based on the captured images respectively captured by first imaging unit 24 and second imaging unit 25. FPGA 21 enables inspection of substrate W and component P after the component is mounted by transmitting the acquired three-dimensional shape data to terminal device P1.

First imaging unit 24 includes lens 241 and image sensor 242. Image sensor 242 is, for example, a solid-state imaging element such as a charged-coupled device (CCD) or a complementary metal-oxide-semiconductor (CMOS), and converts an optical image formed on an imaging plane into an electric signal. First imaging unit 24 captures, as a first captured image, imaging region AR1 (see FIG. 4) in imaging region AR0 based on the control of FPGA 21. First imaging unit 24 outputs the captured first captured image to FPGA 21.

Note that, here, imaging region AR0 is an overlapping region between an imaging region that can be captured by first imaging unit 24 and an imaging region that can be captured by second imaging unit 25.

Second imaging unit 25 includes lens 251 and image sensor 252. Image sensor 252 is, for example, a solid-state imaging element such as a CCD or a CMOS, and converts an optical image formed on an imaging plane into an electric signal. Second imaging unit 25 captures, as a second captured image, imaging region AR2 (see FIG. 4) in imaging region AR0 based on the control of FPGA 21. Second imaging unit 25 outputs the captured second captured image to FPGA 21.

First imaging unit 24 and second imaging unit 25 as an example of a stereo imaging unit are controlled by FPGA 21 to realize a function as a stereo camera. That is, first imaging unit 24 and second imaging unit 25 constitute the stereo camera. First imaging unit 24 and second imaging unit 25 capture (that is, perform stereo imaging) the same imaging region (stereo imaging region) smaller than imaging region AR0 based on the measured substrate height and a displacement amount of the mounting position of component P.

Mounting machine M1 includes communicator 30, mounting control circuit 31, servo amplifier 33, mounting head 34, and nozzle 35.

communicator 30 is connected to terminal device P1 or camera C1 to be able to transmit and receive data. Communicator 30 outputs a control command (electric signal) transmitted from terminal device P1 or camera C1 to mounting control circuit 31. In addition, communicator 30 transmits a notification (electric signal) of mounting completion or the like of component P output from mounting control circuit 31 to terminal device P1 or camera C1.

Mounting control circuit 31 is controlled by terminal device P1 or FPGA 21, refers to a program and data retained in memory 32, and executes the program to realize various functions for mounting component P on substrate W. For example, mounting control circuit 31 executes drive control of servo amplifier 33 and mounting head 34, and realizes functions such as conveyance and mounting of component P to the mounting position on substrate W.

Memory 32 includes, for example, a RAM as a work memory used when each processing of mounting control circuit 31 is executed, and a ROM that stores a program and data that defines an operation of mounting control circuit 31. Data or information generated or acquired by mounting control circuit 31 is temporarily stored in the RAM. A program that defines the operation of mounting control circuit 31 is written to the ROM. Memory 32 may store production data of substrate W.

Note that the production data of substrate W mentioned herein includes identification information (for example, ID, name, model number, and the like) that can identify substrate W, component data of at least one component to be mounted on substrate W, a mounting position and a mounting angle of each component, and the like. The component data includes identification information (for example, ID, name, model number, and the like) that can identify component P, a size, a thickness, and the like of component P.

Servo amplifier 33 drives mounting head 34 and at least one nozzle 35 included in mounting head 34 based on the control of mounting control circuit 31. Servo amplifier 33 can detect a position and a moving speed of mounting head 34, a rotation angle of each nozzle 35, and the like, and controls the movement of mounting head 34 and the elevation, rotation, and the like of each nozzle 35.

Mounting head 34 includes at least one nozzle 35, and conveys component P between a supply position (not illustrated) of component P and a mounting position on substrate W. Note that it has been described that mounting head 34 according to the first exemplary embodiment includes nozzle 35, LD 13, first imaging unit 24, and second imaging unit 25 and moves these units integrally based on a control command from servo amplifier 33. However, the mounting head may not include LD 13, first imaging unit 24, and second imaging unit 25.

Nozzle 35 is controlled by servo amplifier 33 such that component P is sucked and held or the suction at the mounting position of component P is released to mount component P on substrate W.

Terminal device P1 is realized by, for example, a personal computer (PC), a notebook PC, or the like, and executes synchronization control among laser L1, camera C1, and mounting machine M1. Terminal device P1 includes communicator 40, processor 41, and memory 42.

Communicator 40 is connected to laser L1, camera C1, and mounting machine M1 to enable wired communication or wireless communication, and transmits and receives data. Communicator 40 transmits a control command (electric signal) output from processor 41 to each device (laser L1, camera C1, or mounting machine M1). Communicator 40 outputs various kinds of data or various electric signals transmitted from each device to processor 41.

Processor 41 as an example of a calculation unit is formed by using, for example, a CPU, a DSP, or an FPGA, and controls an operation of each unit of processor 41. Processor 41 performs various kinds of processing and control in an integrated manner in cooperation with memory 42. Specifically, processor 41 refers to a program and data retained in memory 42 and executes the program to achieve each function. Hereinafter, each function realized by processor 41 will be described.

Note that in a case where mounting system 100 has a configuration in which terminal device P1 is omitted, the processing of processor 41 may be executed by FPGA 21. In addition, in such a case, memory 22 of camera C1 stores various kinds of data or various kinds of information stored in memory 42, and enables execution of various kinds of processing and control executed by FPGA 21.

Processor 41 generates a control command such as the position of the illumination point of the laser light by LD 13 of laser L1 and the number of illumination points, outputs the control command to communicator 40, and outputs the control command to power supply drive circuit 11 of laser L1. As a result, processor 41 executes the control of the position of the illumination point of the laser light by LD 13, the number of illumination points, and the like.

Processor 41 acquires the positional information of the illumination point transmitted from camera C1. Processor 41 calculates the substrate height of substrate W by using a triangular distance measurement method for the positional information of the illumination point of the laser light at the substrate height included in the production data and the acquired position of the illumination point.

In addition, processor 41 calculates a displacement amount of the mounting position on an XY plane of component P to be mounted based on the calculated substrate height of substrate W and the position of the illumination point of the laser light by LD 13. Processor 41 corrects the mounting position of component P based on the calculated displacement amount of the mounting position, generates a control command for causing camera C1 to capture an imaging region including the corrected mounting position of component P, outputs the control command to communicator 40, and transmits the control command to communicator 20 of camera C1.

Processor 41 acquires a mounting position (for example, a position of a land and the like) of component P transmitted from camera C1 or information on a mounting position (that is, information on a measured value) of mounted component P. Using the triangular distance measurement method, processor 41 calculates a displacement amount between the mounting position of component P included in the production data of substrate W or the mounting position of mounted component P and the mounting position of component P measured by camera C1 (for example, the position of the land and the like) or the mounting position of mounted component P (that is, the measured value).

Processor 41 determines a conveyance position (mounting position) of component P by mounting head 34 and an elevation height of nozzle 35 based on the calculated displacement amount of the mounting position. Processor 41 generates a control command including the determined conveyance position (mounting position) of component P and the determined elevation height of nozzle 35 to mount component P on substrate W, outputs the control command to communicator 40, and transmits the control command to communicator 30 of mounting machine M1.

In addition, processor 41 after component P is mounted determines whether or not there is a variation in the substrate height of substrate W based on the displacement amount of the mounting position of component P transmitted from camera C1, and determines whether or not mounted component P is mounted at the mounting position. In a case where it is determined that there is a variation in the substrate height of substrate W, processor 41 corrects the mounting position of the component in the mounting of another component mounted within a predetermined distance from component P, and determines the conveyance position (mounting position) of component P by mounting head 34 and the elevation height of nozzle 35.

Memory 42 includes, for example, a RAM as a work memory used when each processing of processor 41 is executed, and a ROM that stores a program and data that defines an operation of processor 41. Data or information generated or acquired by processor 41 is temporarily stored in the RAM. A program that defines the operation of processor 41 is written to the ROM. Memory 42 stores information regarding the position and the number of illumination points of the laser light, information regarding imaging regions AR0, AR1, and AR2 of first imaging unit 24 and second imaging unit 25, production data of substrate W, and the like.

Next, an illumination example of laser L1 and an imaging region of camera C1 will be described with reference to each of FIGS. 2 to 4. FIG. 2 is a side view illustrating an illumination example of laser L1 and an imaging region example of camera C1. FIG. 3 is a side view illustrating an illumination example of laser L1 and an imaging region example of camera C1. FIG. 4 is a diagram for describing an example of imaging region AR1 or AR2 of each of first imaging unit 24 and second imaging unit 25.

A region obtained by dividing a length (width) of imaging region AR0 in one of a Y-axis direction or an X-axis direction by half is set as the imaging region of each of first imaging unit 24 and second imaging unit 25.

For example, imaging regions AR1 and AR2 of first imaging unit 24 and second imaging unit 25 are regions obtained by dividing width LA0 of imaging region AR0 in the Y-axis direction by half That is, imaging region AR1 is a half region of imaging region AR0, and imaging region AR2 is a remaining half region of imaging region AR0. Imaging regions AR1 and AR2 of first imaging unit 24 and second imaging unit 25 are imaging regions having width LA1 in the Y-axis direction. Note that imaging regions AR1 and AR2 of first imaging unit 24 and second imaging unit 25 may be regions obtained by dividing the width of imaging region AR0 in the X-axis direction by half. In addition, it goes without saying that sizes of imaging regions AR1 and AR2 of first imaging unit 24 and second imaging unit 25 illustrated in FIGS. 2 to 4 are examples and are not limited thereto.

Mounting head 34 includes first imaging unit 24 and second imaging unit 25, LD 13, and nozzle 35. Note that nozzle 35 illustrated in FIGS. 2 and 3 sucks and holds component P at a distal end of nozzle 35 before component P is mounted.

In each of LD 13, first imaging unit 24, and second imaging unit 25 illustrated in FIG. 4, a distance between LD 13 and each of first imaging unit 24 and second imaging unit 25 is distance B, and is arranged to be separated by distance By in the Y-axis direction and distance Bx in the X-axis direction.

Laser L1 is controlled by terminal device P1 or FPGA 21 of camera C1, and illuminates substrate W and an inside of imaging region AR0 that can be captured by each of first imaging unit 24 and second imaging unit 25 with laser light LP0 by LD 13. In the example illustrated in FIG. 4, illumination point LP1 of the laser light is positioned in imaging region AR1.

First imaging unit 24 and second imaging unit 25 are arranged side by side on a straight line (in FIG. 4, on a straight line along the X-axis direction) along an X axis. Each of first imaging unit 24 and second imaging unit 25 is controlled by FPGA 21 to capture the half regions (imaging region AR1 and imaging region AR2) with respect to imaging region AR0. For example, first imaging unit 24 captures imaging region AR1 in imaging region AR0. Second imaging unit 25 captures imaging region AR2 in imaging region AR0.

FPGA 21 of camera C1 performs image processing on two captured images (first and second captured images) captured by first imaging unit 24 and second imaging unit 25 in parallel. As a result, FPGA 21 can approximately halve an image processing time of the captured image in which entire imaging region AR0 is captured.

Note that the arrangement of each of laser L1, first imaging unit 24, and second imaging unit 25 illustrated in FIG. 4 is an example and is not limited thereto. For example, first imaging unit 24 and second imaging unit 25 may be arranged to have overlapping imaging region AR0. In addition, laser L1 may be arranged at a position where imaging region AR0 on substrate W can be illuminated with the laser light.

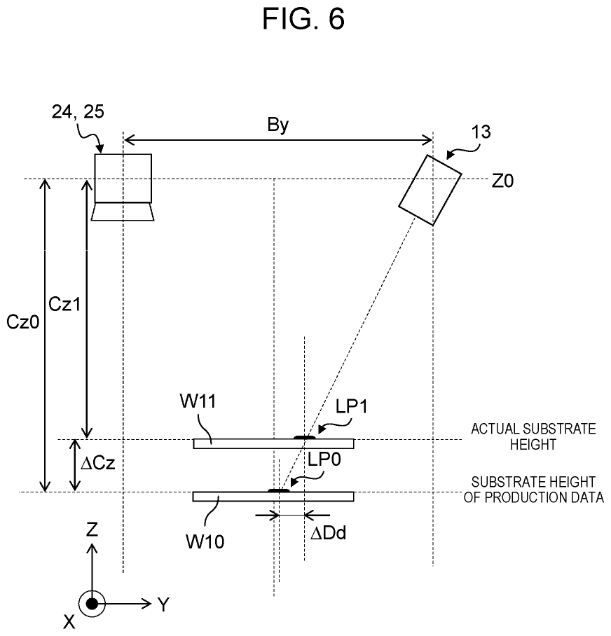

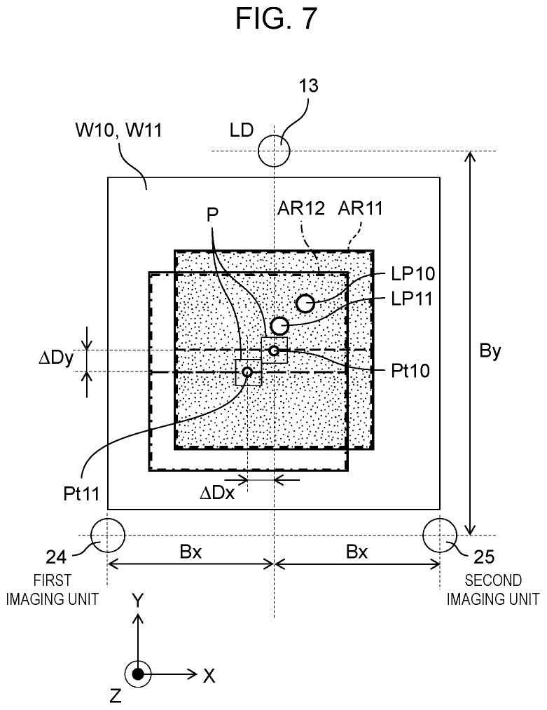

Next, a measurement procedure of the substrate height of substrate W will be described with reference to each of FIGS. 5 to 7. FIG. 5 is a flowchart for describing an operation procedure example of mounting system 100 according to the first exemplary embodiment. FIG. 6 is a side view for describing a substrate height measurement example. FIG. 7 is a top view for describing the substrate height measurement example.

In the flowchart illustrated in FIG. 5, “step 1” including processing of steps St11 to St13 is processing of measuring the substrate height of substrate W executed before component P is mounted. Note that the processing of “step 1” may not be executed for all components mounted on substrate W.

For example, processor 41 of terminal device P1 determines whether or not a distance between the mounting position of the component of which the board height is calculated (that is, already mounted) and a mounting position of a component to be mounted next is within a predetermined distance. In a case where it is determined that the distance between the mounting position of the mounted component and the mounting position of the component to be mounted next is within the predetermined distance, terminal device P1 may omit the processing of “step 1” from pre-mounting processing of the component to be mounted next by using the calculated substrate height as the substrate height corresponding to the component to be mounted next.

In addition, “step 2” including processing of step St14A to step St15A is processing of measuring the mounting position of component P executed before component P is mounted. In addition, “step 2” including processing of step St14B to step St15B is processing of measuring the mounting position of mounted component P executed after component P is mounted.

Laser L1 illuminates a predetermined position on substrate W with the laser light by LD 13 based on the control command transmitted from processor 41 of terminal device P1 (St11).

based on the control command transmitted from terminal device P1, camera C1 narrows the imaging regions of two imaging units (that is, first imaging unit 24 and second imaging unit 25) to a half of entire imaging regions AR0 of two imaging units and captures the narrowed imaging regions (St12). Specifically, first imaging unit 24 captures imaging region AR1 that is a half of imaging region AR0. Second imaging unit 25 captures imaging region AR2 that is a half of imaging region AR0.

Note that the imaging regions of first imaging unit 24 and second imaging unit 25 are not limited to a half of imaging region AR0, and may not have the same size (area). For example, the regions of imaging region AR1 and imaging region AR2 may be set at any ratio such as 9:1, 8:2, 7:3, 6:4 with respect to the size of entire imaging region AR0.

Camera C1 executes image processing of the captured image captured by first imaging unit 24 and image processing of the captured image captured by second imaging unit 25 in parallel, and detects illumination point LP1 appearing in any of the captured images (St12). Camera C1 measures a position (X coordinate and Y coordinate) of detected illumination point LP1 in a horizontal direction (on the XY plane) (St12). Camera C1 transmits the positional information of measured illumination point LP1 to terminal device P1.

Terminal device P1 calculates substrate height Cz1 (that is, an actual substrate height) of substrate W of substrate W11 by using the triangular distance measurement method for the positional information of illumination point LP1 transmitted from camera C1 and the positional information of illumination point LP1 of the laser light at substrate height Cz0 of substrate W10 included in the production data (St13).

Here, the positional information of position Pt10 of illumination point LP1 may be calculated based on an attachment angle of laser L1 with respect to mounting head 34 and a current height of mounting head 34. In addition, calculated substrate height Cz1 may be based on height Z0 (see FIG. 6) of a light receiving surface of image sensor 242 or 252 of first imaging unit 24 or second imaging unit 25.

Terminal device P1 calculates displacement amount ΔCz of the substrate height based on difference ΔDd between calculated actual substrate height Cz1 of substrate W11 and substrate height Cz0 (that is, an ideal substrate height) of substrate W10 included in the production data. Terminal device P1 calculates displacement amount ΔDx in the X direction and displacement amount ΔDy in the Y direction of the mounting position of component P in a case where the substrate height is displaced by displacement amount ΔCz by using (Expression 1) based on the triangular distance measurement method for displacement amount ΔCz of the substrate height (St14A). Note that focal distance F in (Expression 1) is a focal distance of first imaging unit 24 and second imaging unit 25.

Note that position Pt10 of component P illustrated in FIG. 7 indicates a mounting position of component P at actual substrate height Cz1. Position Pt11 of component P indicates a mounting position of component P at substrate height Cz0 of substrate W included in the production data. In addition, displacement amount ΔDx is a displacement amount (distance) in the X-axis direction between position Pt10 and position Pt11 in the X direction. Displacement amount ΔDy is a displacement amount (distance) in the Y-axis direction between position Pt10 and position Pt11 in the Y direction.

$$\{ \begin{matrix}Δ Dx = \frac{Bx \times F}{Cz 0 - Δ Cz} - \frac{Bx \times F}{Cz 0} = BxF ( \frac{1}{Cz 0 - Δ Cz} - \frac{1}{Cz 0} ) \\ Δ Dy = \frac{By \times F}{Cz 0 - Δ Cz} - \frac{By \times F}{Cz 0} = ByF ( \frac{1}{Cz 0 - Δ Cz} - \frac{1}{Cz 0} )\end{matrix} \qquad [ Math . 1 ]$$

Terminal device P1 calculates a mounting position of component P at substrate height Cz1 of substrate W11 based on each of calculated displacement amount ΔDx and displacement amount ΔDy of the mounting position of component P. Terminal device P1 narrows the imaging region stereoscopically captured by each of first imaging unit 24 and second imaging unit 25 to a range smaller than imaging region AR0 based on calculated displacement amount ΔDx and displacement amount ΔDy of the mounting position of component P, and generates information on the narrowed imaging region and a control command for requesting high-speed stereo imaging. Terminal device P1 transmits the information on the imaging region and the control command to camera C1 in association with each other (St15A).

Camera C1 executes high-speed stereo imaging by narrowing the imaging region of each of first imaging unit 24 and second imaging unit 25 to a region smaller than imaging region AR0 based on the information on the imaging region transmitted from terminal device P1 (St15A). Camera C1 acquires a three-dimensional shape of a land or the like on substrate W before the component is mounted based on two captured images stereoscopically captured by first imaging unit 24 and second imaging unit 25 (St15A). Camera C1 transmits the acquired three-dimensional shape data to terminal device P1. As a result, camera C1 can reduce a processing time required for the image processing of two captured images stereoscopically captured by first imaging unit 24 and second imaging unit 25 by narrowing the imaging regions.

Terminal device P1 calculates a mounting position (that is, a relative position between nozzle 35 and the mounting position of component P on substrate W) of component P on substrate W with respect to component P sucked by nozzle 35 based on the three-dimensional shape data transmitted from camera C1. Based on the calculated relative position, terminal device P1 generates a control command including a drive amount of each of the X-, Y-, and Z-axis directions of mounting head 34 for mounting component P on substrate W, and transmits the control command to mounting machine M1. Mounting machine M1 mounts component P on substrate W based on the control command transmitted from terminal device P1.

In addition, after component P is mounted, camera C1 calculates the displacement amount of the mounting position (XY position) of mounted component P by using the triangular distance measurement method for information on actual board height Cz1 calculated in the processing of step St13 (St14B). Camera C1 calculates the position (XY coordinates) of component P captured by each of first imaging unit 24 and second imaging unit 25 based on the displacement amount of the mounting position of mounted component P (St14B).

Camera C1 narrows the imaging region of each of first imaging unit 24 and second imaging unit 25 to an imaging region smaller than imaging region AR0 and including the mounting position of mounted component P based on the calculated position (XY coordinates) of mounted component P (St15B). After the imaging regions are narrowed, camera C1 executes high-speed stereo imaging by each of first imaging unit 24 and second imaging unit 25 (St15B). Camera C1 acquires the three-dimensional shape of component P mounted on substrate W based on two captured images stereoscopically captured by first imaging unit 24 and second imaging unit 25 (St15B). Camera C1 transmits the acquired three-dimensional shape data to terminal device P1.

As a result, camera C1 can reduce a processing time required for image processing using two captured images stereoscopically captured by first imaging unit 24 and second imaging unit 25. The image processing in step St15B is image processing for measuring the position of mounted component P.

Terminal device P1 calculates the mounting position of component P mounted on substrate W based on the three-dimensional shape data transmitted from camera C1. Terminal device P1 executes inspection of substrate W and component P mounted on substrate W based on the calculated mounting position.

As described above, mounting system 100 according to the first exemplary embodiment can shorten a time required for the image processing of the captured image to approximately half by setting first imaging unit 24 and second imaging unit 25 to imaging regions AR1 and AR2 that are halves of imaging region AR0 during the measurement of the substrate height. In addition, mounting system 100 can shorten the time required for the image processing of two captured images obtained by the stereo imaging by calculating the displacement amount of the mounting position of component P based on the displacement amount of the substrate height and further narrowing the imaging regions. As a result, since mounting system 100 can shorten the time required for the image processing, it is possible to improve production efficiency of substrate W.

Note that, in the description of FIG. 5, the processing executed by processor 41 of terminal device P1 may be executed by FPGA 21 of camera C1.

Hereinafter, other laser illumination examples and other use case examples using height measurement processing of the first exemplary embodiment will be described.

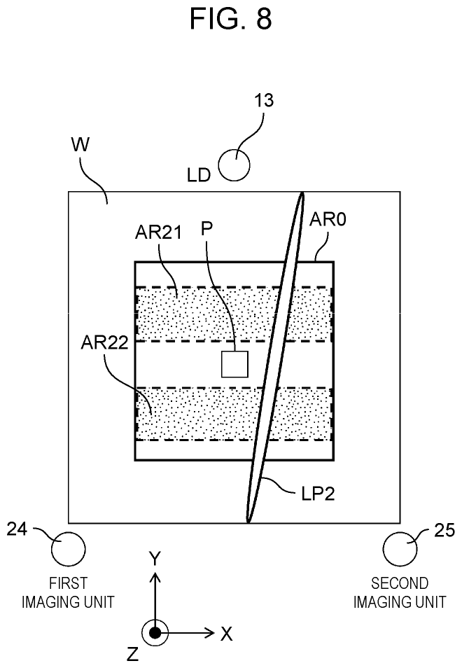

A second laser illumination example of LD 13 will be described with reference to FIG. 8. FIG. 8 is a diagram for describing the second laser illumination example.

In the second laser illumination example, LD 13 illuminates laser light having a linear shape crossing imaging region AR0 on substrate W in a predetermined direction. In the second laser illumination example, imaging region AR 21 of first imaging unit 24 and imaging region AR22 of second imaging unit 25 may be set to be less than or equal to a half of imaging region AR0. As a result, camera C1 can further shorten the image processing time in processing of measuring the substrate height of substrate W based on the position of the laser light illuminated onto substrate W.

Note that the predetermined direction in the second laser illumination example is a direction not parallel to a direction along long sides of imaging region AR21 of first imaging unit 24 and imaging region AR22 of second imaging unit 25 (in the example illustrated in FIG. 8, the X direction). Note that the predetermined direction is desirably a direction substantially orthogonal to the long side (in the example illustrated in FIG. 8, the Y direction), but is not limited thereto.

In addition, in the second laser illumination example, camera C1 may measure the substrate height by using only the captured image captured by any one of first imaging unit 24 or second imaging unit 25.

For example, in a case where imaging region AR21 of first imaging unit 24 and imaging region AR22 of second imaging unit 25 each have a size of ¼ of imaging region AR0, camera C1 can further shorten the image processing time of two captured images captured by first imaging unit 24 and second imaging unit 25 to half as compared with the laser illumination example illustrated in FIG. 3.

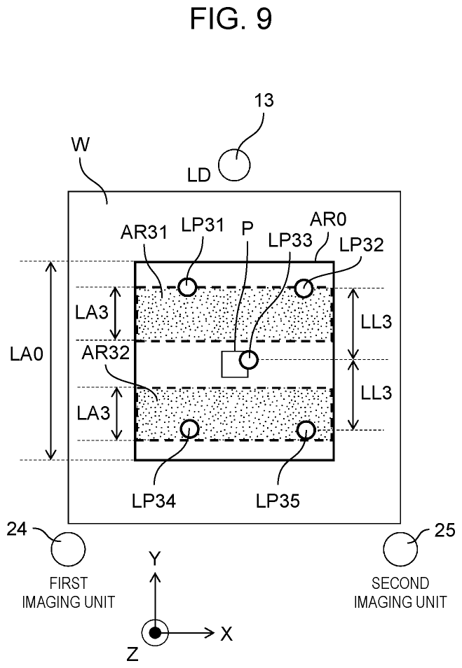

A third laser illumination example of LD 13 will be described with reference to FIG. 9. FIG. 9 is a diagram for describing a third laser illumination example.

In the third laser illumination example, LD 13 illuminates the inside of imaging region AR0 on substrate W with a plurality of laser light rays each having a spot shape. Note that, in the example illustrated in FIG. 9, five spot-shaped laser light rays are illuminated from LD 13, but the number of illumination points may be two or more. In the third laser illumination example, imaging region AR31 of first imaging unit 24 and imaging region AR32 of second imaging unit 25 may be set to be less than or equal to a half of imaging region AR0.

In addition, in the third laser illumination example, illumination positions of two or more laser light rays may be randomly set, or an illumination pattern may be set such that the laser light rays are illuminated at predetermined positions and at predetermined intervals. In a case where the illumination pattern is set at the illumination positions of the laser light rays, width LA3 in the Y-axis direction between imaging region AR31 of first imaging unit 24 and imaging region AR32 of second imaging unit 25 may be determined based on the illumination interval between the laser light rays in the Y-axis direction based on the illumination pattern.

For example, width LA3 between imaging region AR31 of first imaging unit 24 and imaging region AR32 of second imaging unit 25 may be set to be less than or equal to a half of width LA0 of imaging region AR0 in the Y-axis direction and more than or equal to distance LL3 between illumination points LP31, LP32, LP34, and LP35 and illumination point LP33 in the Y-axis direction. As a result, camera C1 can further reduce the image processing time in processing of measuring the substrate height of substrate W based on the illumination positions of the laser light rays illuminated onto substrate W.

Note that, in the third laser illumination example, in a case where the captured image of imaging region AR31 captured by first imaging unit 24 and the captured image of imaging region AR32 captured by second imaging unit 25 each include the illumination point, camera C1 may measure the substrate height by using only the captured image captured by any one of first imaging unit 24 or second imaging unit 25.

In addition, in the third laser illumination example, camera C1 may further measure an inclination of substrate W based on substrate heights at positions of a plurality of illumination points appearing in the captured image of imaging region AR31 and the captured image of imaging region AR32.

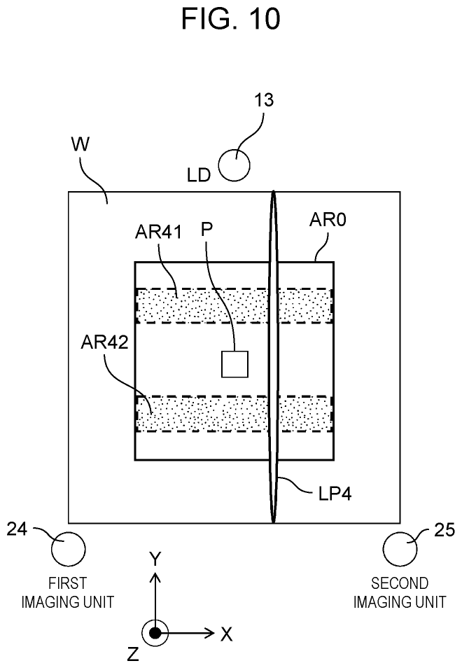

A fourth laser illumination example of LD 13 will be described with reference to FIG. 10. FIG. 10 is a diagram for describing the fourth laser illumination example.

In the fourth laser illumination example, LD 13 illuminates laser light having a linear shape crossing imaging region AR0 on substrate W in the Y-axis direction, that is, crossing in a direction substantially orthogonal to long sides of imaging region AR41 of first imaging unit 24 and imaging region AR42 of second imaging unit 25. In the fourth laser illumination example, imaging region AR41 of first imaging unit 24 and imaging region AR42 of second imaging unit 25 may be set to be less than or equal to a half of imaging region AR0.

As a result, camera C1 can further shorten the image processing time in processing of measuring the substrate height of substrate W based on the position of the laser light illuminated onto substrate W.

In addition, in the fourth laser illumination example, camera C1 may measure the substrate height by using only the captured image captured by any one of first imaging unit 24 or second imaging unit 25.

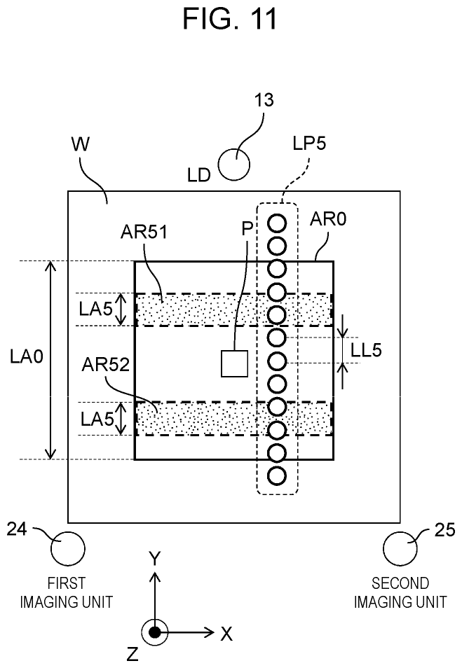

A fifth laser illumination example of LD 13 will be described with reference to FIG. 11. FIG. 11 is a diagram for describing the fifth laser illumination example.

In the fifth laser illumination example, LD 13 illuminates a plurality of laser light rays each having a spot shape to cross the inside of imaging region AR0 on substrate W in a direction substantially orthogonal to long sides of imaging region AR51 of first imaging unit 24 and imaging region AR52 of second imaging unit 25. In the fifth laser illumination example, width LA5 between imaging region AR51 of first imaging unit 24 and imaging region AR52 of second imaging unit 25 is set to be less than a half of imaging region AR0 in the Y-axis direction and to be more than or equal to illumination interval LL5 of illumination point LP5 having a spot shape.

As a result, camera C1 can further shorten the image processing time in processing of measuring the substrate height of substrate W based on illumination point LP5 illuminated onto substrate W.

Note that, in the fifth laser illumination example, camera C1 may measure the substrate height by using only the captured image captured by any one of first imaging unit 24 or second imaging unit 25.

In addition, in the fifth laser illumination example, camera C1 may further measure an inclination of substrate W based on substrate heights at positions of a plurality of illumination points appearing in the captured image of imaging region AR51 and the captured image of imaging region AR52.

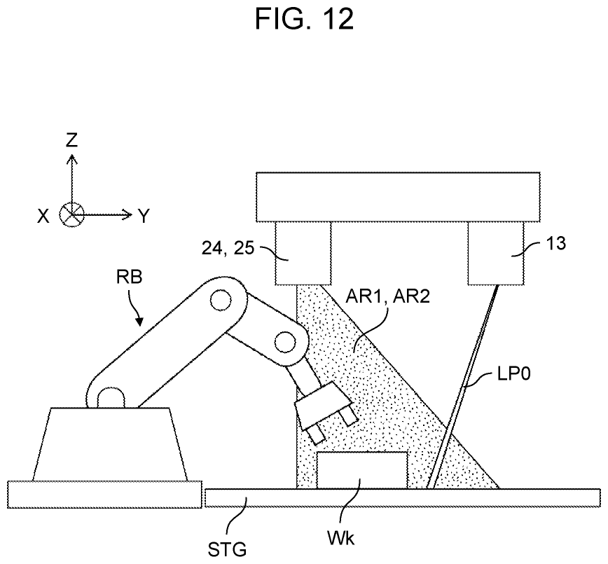

Another use case will be described with reference to FIG. 12. FIG. 12 is a diagram for describing another use case example of the height measurement processing in the first exemplary embodiment.

Robot RB in another use case illustrated in FIG. 12 has a robot hand, and executes sorting and the like of workpiece Wk (for example, food, component, package, or the like) on stage STG. In such a case, mounting system 100 includes robot RB instead of mounting machine M1, and captures the illumination point of laser light LP0 illuminated onto stage STG by laser L1 by each of first imaging unit 24 and second imaging unit 25 of camera C1. Mounting system 100 executes image processing of captured two images in parallel, and measures a stage height of stage STG.

As a result, mounting system 100 can hold workpiece Wk on stage STG with the robot hand to move (convey) workpiece Wk to another place or move (convey) workpiece Wk from another place onto stage STG.

As described above, mounting machine M1 according to the first exemplary embodiment includes first imaging unit 24 that captures imaging region AR1 (an example of a first imaging region) smaller than a predetermined imaging region in imaging region AR0 (an example of a predetermined imaging region) on substrate W illuminated with the laser light, second imaging unit 25 that captures imaging region AR2 (an example of a second imaging region) including at least a region smaller than the inside of imaging region AR0 and different from imaging region AR1 in imaging region AR0, and processor 41 (an example of a calculation unit) that detects the position (an example of an illumination position) of illumination point LP1 of the laser light from at least one captured image among the captured images captured by first imaging unit 24 and second imaging unit 25 and calculates the substrate height based on the detected position of illumination point LP1. Note that a computer mentioned herein may be any of terminal device P1, mounting machine M1, or camera C1. In addition, two cameras mentioned herein indicate first imaging unit 24 and second imaging unit 25.

Thus, in mounting machine M1 according to the first exemplary embodiment, during the measurement of the substrate height of substrate W, imaging regions AR1 and AR2 smaller than imaging region AR0 are captured by first imaging unit 24 and second imaging unit 25, and thus, the time required for the image processing of the captured images can be shortened to the time corresponding to the sizes of imaging regions AR1 and AR2. Accordingly, since mounting machine M1 can shorten the time required for the image processing, the production efficiency of substrate W can be improved.

In addition, as described above, mounting machine M1 according to the first exemplary embodiment further includes first imaging unit 24 and second imaging unit 25 (an example of the stereo imaging unit) that perform stereo imaging by setting the imaging regions (that is, imaging regions AR1 and AR2) of first imaging unit 24 and second imaging unit 25 to be smaller based on the substrate height. As a result, mounting machine M1 according to the first exemplary embodiment can narrow the imaging regions stereoscopically imaged by first imaging unit 24 and second imaging unit 25 to regions smaller than imaging region AR0 based on the calculated substrate height. Accordingly, mounting machine M1 can shorten the time required for the image processing of the captured images captured by the stereo imaging. Accordingly, mounting machine M1 can shorten the time required to calculate the mounting position of component P and can improve the production efficiency of substrate W.

In addition, as described above, in mounting machine M1 according to the first exemplary embodiment, the laser light is linearly illuminated onto substrate W (see FIGS. 8 and 10). Imaging regions AR21 and AR41 and imaging regions AR22 and AR42 each have a substantially rectangular shape, and a longitudinal direction of the substantially rectangular shape is not parallel to the laser light. As a result, even in a case where the imaging regions of first imaging unit 24 and second imaging unit 25 are set to be smaller (that is, in a case where the imaging region is set to be less than or equal to a half of imaging region AR0), since the illumination point of the laser light is included in any of the imaging regions, mounting machine M1 according to the first exemplary embodiment can measure the substrate height based on the position of the illumination point. Accordingly, since mounting machine M1 can shorten the time required for the image processing, the production efficiency of substrate W can be further improved.

In addition, as described above, in mounting machine M1 according to the first exemplary embodiment, in imaging region AR41 and imaging region AR42, the longitudinal direction is substantially orthogonal to the laser light (see FIG. 10). As a result, even in a case where the imaging regions of first imaging unit 24 and second imaging unit 25 are set to be smaller (that is, in a case where the imaging region is set to be less than or equal to a half of imaging region AR0), since the illumination point of the laser light is included in any of the imaging regions, mounting machine M1 according to the first exemplary embodiment can measure the substrate height based on the position of the illumination point. Accordingly, since mounting machine M1 can shorten the time required for the image processing, the production efficiency of substrate W can be further improved.

In addition, as described above, in mounting machine M1 according to the first exemplary embodiment, the laser light is illuminated onto the plurality of illumination positions (for example, the positions of the plurality of illumination points LP31 to LP35 illustrated in FIG. 9, the position of illumination points LP5 illustrated in FIG. 10, and the like) on substrate W. As a result, even in a case where the imaging regions of first imaging unit 24 and second imaging unit 25 are set to be smaller (that is, in a case where the imaging region is set to be less than or equal to a half of imaging region AR0), since the illumination point of the laser light is included in any of the imaging regions, mounting machine M1 according to the first exemplary embodiment can measure the substrate height based on the position of the illumination point. Accordingly, since mounting machine M1 can shorten the time required for the image processing, the production efficiency of substrate W can be further improved.

In addition, as described above, in mounting machine M1 according to the first exemplary embodiment, the laser light is illuminated onto the plurality of positions (for example, the positions of the plurality of illumination points LP31 to LP35 illustrated in FIG. 9, the position of illumination points LP5 illustrated in FIG. 11, and the like) on substrate W at predetermined intervals (for example, distance LL3 illustrated in FIG. 9, illumination interval LL5 illustrated in FIG. 10, and the like). As a result, even in a case where the imaging regions of first imaging unit 24 and second imaging unit 25 are set to be smaller (that is, in a case where the imaging region is set to be less than or equal to a half of imaging region AR0), since the illumination point of the laser light is included in any of the imaging regions, mounting machine M1 according to the first exemplary embodiment can measure the substrate height based on the position of the illumination point. Accordingly, since mounting machine M1 can shorten the time required for the image processing, the production efficiency of substrate W can be further improved.

In addition, as described above, in mounting machine M1 according to the first exemplary embodiment, the laser light is illuminated onto the plurality of positions on the straight line on substrate W (for example, the position of illumination point LP5 illustrated in FIG. 11, and the like). Imaging region AR51 and imaging region AR52 each have a substantially rectangular shape, and the longitudinal direction of the substantially rectangular shape is not parallel to the laser light. As a result, even in a case where the imaging regions of first imaging unit 24 and second imaging unit 25 are set to be smaller (that is, in a case where the imaging region is set to be less than or equal to a half of imaging region AR0), since the illumination point of the laser light is included in any of the imaging regions, mounting machine M1 according to the first exemplary embodiment can measure the substrate height based on the position of the illumination point. Accordingly, since mounting machine M1 can shorten the time required for the image processing, the production efficiency of substrate W can be further improved.

In addition, as described above, in mounting machine M1 according to the first exemplary embodiment, in imaging region AR51 and imaging region AR52, the longitudinal direction is substantially orthogonal to the laser light (see FIG. 11). As a result, even in a case where the imaging regions of first imaging unit 24 and second imaging unit 25 are set to be smaller (that is, in a case where the imaging region is set to be less than or equal to a half of imaging region AR0), since the illumination point of the laser light is included in any of the imaging regions, mounting machine M1 according to the first exemplary embodiment can measure the substrate height based on the position of the illumination point. Accordingly, since mounting machine M1 can shorten the time required for the image processing, the production efficiency of substrate W can be further improved.

In addition, as described above, in mounting machine M1 according to the first exemplary embodiment, imaging regions AR1, AR21, AR31, AR41, and AR51 and imaging regions AR2, AR22, AR32, AR42, and AR52 are each less than or equal to a half of imaging region AR0 (see FIGS. 8 to 11). As a result, mounting machine M1 according to the first exemplary embodiment can shorten the time required for the image processing as the size of the imaging region of each of first imaging unit 24 and second imaging unit 25 is reduced, and the production efficiency of substrate W can be further improved.

In addition, as described above, in mounting machine M1 according to the first exemplary embodiment, imaging region AR1 is a half of imaging region AR0. Imaging region AR2 is a half of imaging region AR0 and is a region different from imaging region AR1. As a result, mounting machine M1 according to the first exemplary embodiment can shorten the time required for the image processing of the captured image to approximately a half by capturing imaging regions AR1 and AR2 that are halves of imaging region AR0 with respect to first imaging unit 24 and second imaging unit 25. Accordingly, since mounting machine M1 can shorten the time required for the image processing, the production efficiency of substrate W can be improved.

In addition, as described above, in mounting machine M1 according to the first exemplary embodiment, imaging regions AR1, AR21, AR31, AR41, and AR51 and imaging regions AR2, AR22, AR32, AR42, and AR52 each have a substantially rectangular shape, and are less than or equal to a half of imaging region AR0, and a length in a direction orthogonal to the longitudinal direction of the substantially rectangular shape is a length more than or equal to a predetermined interval (for example, distance LL3 illustrated in FIG. 9, illumination interval LL5 illustrated in FIG. 10, and the like). As a result, in mounting machine M1 according to the first exemplary embodiment, the illumination point is included in at least one imaging region of the imaging regions of first imaging unit 24 and second imaging unit 25. In addition, mounting machine M1 can shorten the time required for the image processing, and can further improve the production efficiency of substrate W.

Although various exemplary embodiments have been described above with reference to the accompanying drawings, the present disclosure is not limited to such examples. It is apparent that those skilled in the art can conceive various modification examples, correction examples, substitution examples, addition examples, removal examples, and equivalent examples within the scope described in the attached claims, and those examples are understood to be within the technical scope of the present disclosure. In addition, each component in the various exemplary embodiments described above may be appropriately combined without departing from the spirit of the disclosure.

The present disclosure is useful as a presentation of a mounting machine and a mounting method that allows the measurement of the substrate height to be more efficient.

What is claimed is:

1. A mounting machine comprising:
a first imaging unit that captures, as a first captured image, a first imaging region in a predetermined imaging region on a substrate illuminated with laser light, the first imaging region being smaller than the predetermined imaging region;
a second imaging unit that captures, as a second captured image, a second imaging region in the predetermined imaging region, the second imaging region smaller than the predetermined imaging region and including at least a region different from the first imaging region; and
a calculation unit that detects an illumination position of the laser light from at least one captured image of the first captured image or the second captured image, and calculates a height of the substrate based on the detected illumination position.

2. The mounting machine according to claim 1, wherein
the first imaging unit and the second imaging unit constitute a stereo camera, and
each of the first imaging unit and the second imaging unit captures a stereo imaging region based on the height of the substrate, the stereo imaging region being smaller than the predetermined imaging region.

3. The mounting machine according to claim 1, wherein
the laser light is linearly illuminated on the substrate in a predetermined direction,
each of the first imaging region and the second imaging region has a substantially rectangular shape, and
a longitudinal direction of the substantially rectangular shape and the predetermined direction are not parallel.

4. The mounting machine according to claim 3, wherein the longitudinal direction and the predetermined direction are substantially orthogonal.

5. The mounting machine according to claim 1, wherein the laser light is illuminated onto a plurality of positions on the substrate.

6. The mounting machine according to claim 1, wherein the laser light is illuminated onto a plurality of positions at a predetermined interval.

7. The mounting machine according to claim 1, wherein
the laser light is illuminated onto a plurality of positions on a straight line on the substrate,
each of the first imaging region and the second imaging region has a substantially rectangular shape, and
a longitudinal direction of the substantially rectangular shape and the straight line are not parallel.

8. The mounting machine according to claim 7, wherein the longitudinal direction and the straight line are substantially orthogonal.

9. The mounting machine according to claim 1, wherein each of the first imaging region and the second imaging region is a region less than or equal to half of the predetermined imaging region.

10. The mounting machine according to claim 1, wherein
the first imaging region is a half region of the predetermined imaging region, and
the second imaging region is a remaining half region of the predetermined imaging region.

11. The mounting machine according to claim 6, wherein
each of the first imaging region and the second imaging region has a substantially rectangular shape, and is less than or equal to a half of the predetermined imaging region, and
a length of the substantially rectangular shape in a direction orthogonal to a longitudinal direction of the substantially rectangular shape is more than or equal to the predetermined interval.

12. A method for measuring a substrate height executed by a computer connected to two cameras that capture a predetermined imaging region on a substrate illuminated with laser light, the method comprising:
capturing, as a first captured image, a first imaging region in the predetermined imaging region, the first imaging region being smaller than the predetermined imaging region;
capturing, as a second captured image, a second imaging region in the predetermined imaging region, the second imaging region smaller than the predetermined imaging region and including at least a region different from the first imaging region;
detecting an illumination position of the laser light from at least one captured image of the first captured image or the second captured image; and
calculating a height of the substrate based on the detected illumination position.
